(19) United States
(12) Patent Application Publication
(10) Pub. No.: US 2017/0069635 A1
(43) Pub. Date: Mar. 9, 2017

(54) SEMICONDUCTOR DEVICE AND METHOD FOR MANUFACTURING THE SAME

(71) Applicant: Kabushiki Kaisha Toshiba, Minato-ku (JP)

(72) Inventors: Hikari TAJIMA, Mitaka (JP); Yuki Sekino, Yokohama (JP); Masaki Kondo, Yokkaichi (JP)

(73) Assignee: Kabushiki Kaisha Toshiba, Minato-ku (JP)

(21) Appl. No.: 15/066,569

(22) Filed: Mar. 10, 2016

Related U.S. Application Data
(60) Provisional application No. 62/213,849, filed on Sep. 3, 2015.

(51) Int. Cl. H01L 27/115; H01L 29/66; H01L 29/06

(52) U.S. Cl. CPC H01L 27/1157; H01L 27/11582; H01L 29/0638; H01L 29/66537

(57) ABSTRACT

According to one embodiment, a semiconductor device includes a stacked body, a semiconductor body of a first conductivity type, a memory film, and a first semiconductor layer of the first conductivity type. The stacked body includes a plurality of electrode layers stacked with an insulator interposed. The semiconductor body includes a first portion, a second portion, and a third portion. The second portion is provided between the first portion and the third portion. The memory film is provided between the semiconductor body and at least a part of the electrode layers. A concentration of a first conductivity type carrier of the first semiconductor layer is higher than a concentration of the first conductivity type carrier of the third portion. The second portion includes a channel of a selection transistor. The third portion includes a channel of a memory cell.

### CROSS-REFERENCE TO RELATED APPLICATION

This application is based upon and claims the benefit of priority from U.S. Provisional Patent Application 62/213,849, filed on Sep. 3, 2015; the entire contents of which are incorporated herein by reference.

### FIELD

Embodiments described herein relate generally to a semiconductor device and a method for manufacturing the same.

### BACKGROUND

A memory device having a three-dimensional structure has been proposed in which memory holes are made in a stacked body in which multiple electrode layers are stacked, and charge storage films and semiconductor films are provided to extend in the stacking direction of the stacked body in the memory holes. The memory device includes multiple memory cells connected in series between a drain-side selection transistor and a source-side transistor. To increase the density of the memory device, the diameter of the memory holes and the width of the electrode layers are shrunk. As the shrinking progresses, a threshold voltage Vth of the selection transistor decreases. When the threshold voltage Vth decreases, the selection transistor cannot be switched OFF, even when a gate voltage Vg of the selection transistor is 0 V. Therefore, the off-leakage current increases.

### BRIEF DESCRIPTION OF THE DRAWINGS

FIG. 1 is a schematic perspective view of a memory cell array of a semiconductor device of a first embodiment;

FIG. 2 is a schematic cross-sectional view of a column of the semiconductor device of the first embodiment;

FIG. 3 is a schematic cross-sectional view of a semiconductor body and a memory film;

FIG. 4 is a figure showing a concentration profile of impurities of the semiconductor body;

FIG. 5 to FIG. 18 are schematic cross-sectional views showing a method for manufacturing the semiconductor device of the first embodiment;

FIG. 19 is a schematic cross-sectional view of the column of a semiconductor device of a second embodiment;

FIG. 20 to FIG. 22 are schematic cross-sectional views showing a method for manufacturing the semiconductor device of the second embodiment;

FIG. 23 is a schematic cross-sectional view of the column of a semiconductor device of a third embodiment;

FIG. 24 to FIG. 26 are schematic cross-sectional views showing a method for manufacturing the semiconductor device of the third embodiment;

FIG. 27 is a schematic cross-sectional view of the column of a semiconductor device of a fourth embodiment;

FIG. 28 is a schematic cross-sectional view of the column of a semiconductor device of a fifth embodiment; and

FIG. 29 is a schematic cross-sectional view of the column of a semiconductor device of a sixth embodiment.

### DETAILED DESCRIPTION

According to one embodiment, a semiconductor device includes a stacked body, a semiconductor body of a first conductivity type, a memory film, and a first semiconductor layer of the first conductivity type. The stacked body includes a plurality of electrode layers stacked with an insulator interposed. The semiconductor body of a first conductivity type extends through the stacked body in a stacking direction of the stacked body. The semiconductor body includes, along the stacking direction of the stacked body, a first portion, a second portion, and a third portion. The second portion is provided between the first portion and the third portion. The memory film is provided between the semiconductor body and at least a part of the electrode layers. The memory film includes a charge storage portion. The first semiconductor layer of the first conductivity type is provided in the second portion. A concentration of a first conductivity type carrier of the first semiconductor layer is higher than a concentration of the first conductivity type carrier of the third portion. The second portion includes a channel of a selection transistor. The third portion includes a channel of a memory cell.

Embodiments will now be described with reference to the drawings. The same components are marked with the same reference numerals in the drawings.

The semiconductor device of the embodiments is a semiconductor memory device including a memory cell array.

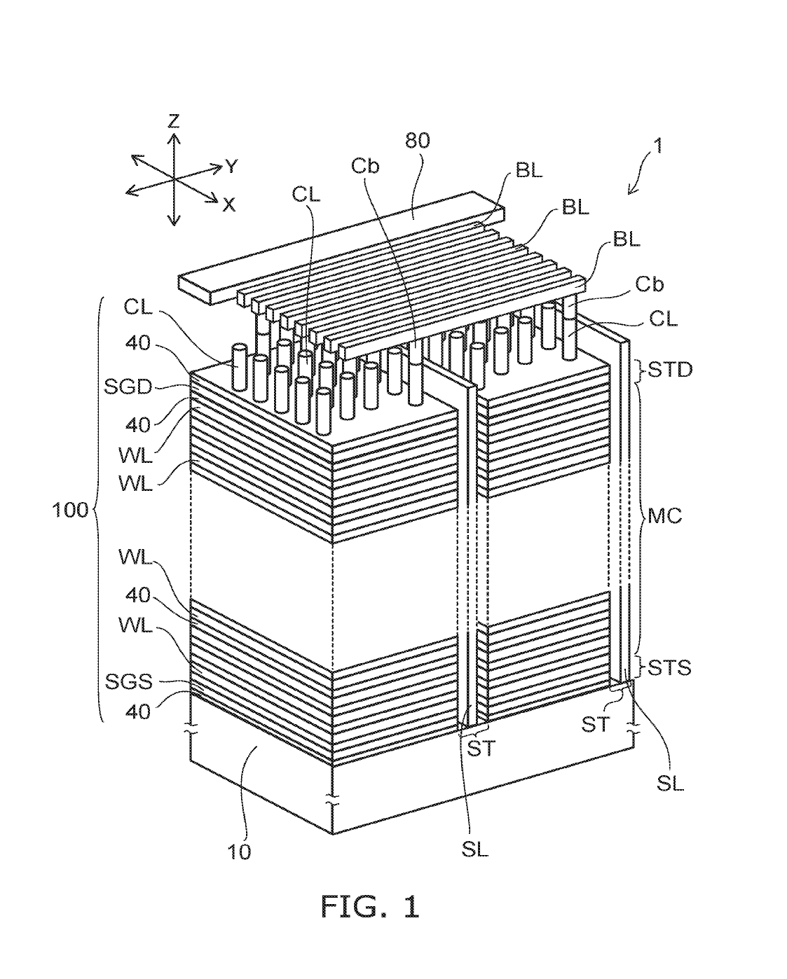

FIG. 1 is a schematic perspective view of the memory cell array of the semiconductor device of a first embodiment.

In FIG. 1, two mutually-orthogonal directions parallel to a major surface of a substrate 10 are taken as an X-direction (a first direction) and a Y-direction (a second direction); and a direction orthogonal to both the X-direction and the Y-direction is taken as a Z-direction (a third direction, i.e., a stacking direction).

The memory cell array 1 includes the multiple separation portions ST, multiple columns CL, and a stacked body 100 that includes a drain-side selection gate SGD, multiple word lines WL, and a source-side selection gate SGS. The source-side selection gate (the lower gate layer) SGS is provided above the substrate 10. The multiple word lines WL are provided above the source-side selection gate SGS. The drain-side selection gate (the upper gate layer) SGD is provided above the multiple word lines WL. The drain-side selection gate SGD, the multiple word lines WL, and the source-side selection gate SGS are multiple electrode layers. The number of stacks of electrode layers is arbitrary.

The multiple electrode layers (SGD, WL, and SGS) are stacked to be separated from each other. Insulators 40 are disposed between the multiple electrode layers (SGD, WL, and SGS). The insulators 40 may be insulators such as silicon oxide films, etc., or may be air gaps.

At least one of the selection gates SGD is used as a gate electrode of a drain-side selection transistor STD. At least one of the selection gates SGS is used as a gate electrode of a source-side selection transistor STS. Multiple memory cells MC are connected in series between the drain-side selection transistor STD and the source-side selection transistor STS. One of the word lines WL is used as a gate electrode of the memory cell MC.

The drain-side selection transistor STD shown in FIG. 1 is a single-gate type. One of the selection gates SGD is used as a gate electrode of the single-gate type drain-side selection transistor STD. The drain-side selection transistor STD may be a multi-gate type. Multiple selection gates SGD are used as the gate electrodes of the multi-gate type drain-side selection transistor STD. The same selection signal is supplied to the multiple gate electrodes. Thereby, the multiple gate electrodes function as one gate electrode. For the source-side selection transistor STS as well, the type of the transistor may be the single-gate type or the multi-gate type.

The multiple separation portions ST are provided in the stacked body 100. The separation portions ST extend in the stacking direction (the Z-direction) and the X-direction through the stacked body 100. The separation portions ST divide the stacked body 100 into a plurality in the Y-direction. The regions separated by the separation portions ST are called “blocks.”

Source layers SL are disposed in the separation portions ST. The source layers SL are insulated from the stacked body 100 and spread, for example, in a plate configuration in the Z-direction and the X-direction. An upper layer interconnect 80 is disposed above the source layers SL. The upper layer interconnect 80 extends in the Y-direction. The upper layer interconnect 80 is electrically connected to the multiple source layers SL arranged along the Y-direction.

The multiple columns CL are provided in the stacked body 100 divided by the separation portions ST. The columns CL extend in the stacking direction (the Z-direction). For example, the columns CL are formed in circular columnar configurations or elliptical columnar configurations. For example, the columns CL are disposed in a staggered lattice configuration or a square lattice configuration in the memory cell array 1. The drain-side selection transistor STD, the multiple memory cells MC, and the source-side selection transistor STS are disposed in the column CL.

Multiple bit lines BL are disposed above the upper end portions of the columns CL. The multiple bit lines BL extend in the Y-direction. The upper end portion of the column CL is electrically connected to one of the bit lines BL via a contact Cb. One bit line is electrically connected to one column CL selected from each of the blocks.

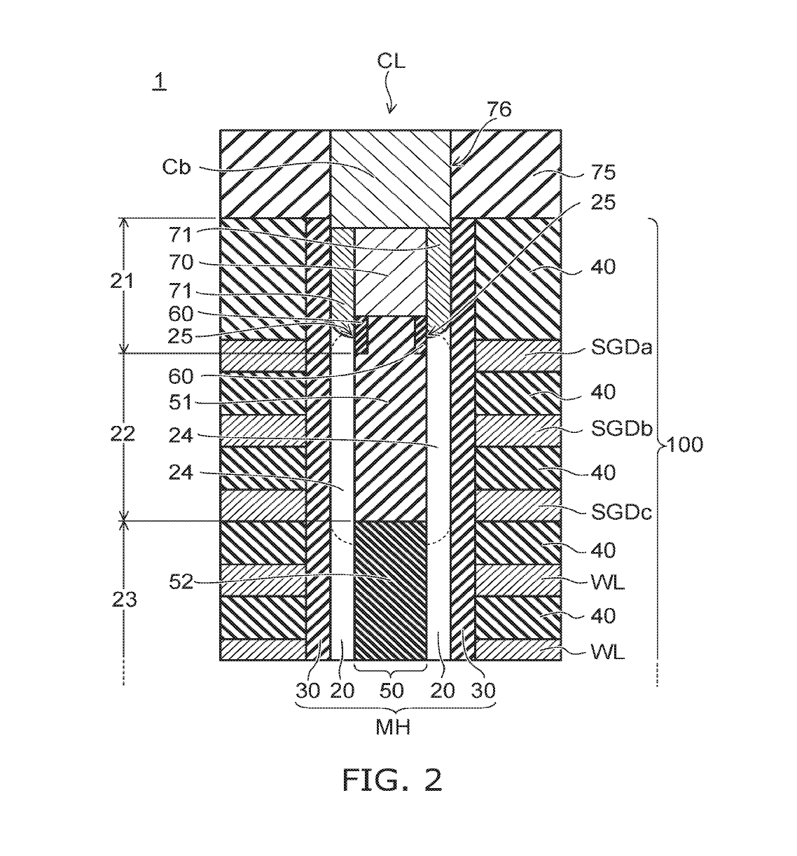

FIG. 2 is a schematic cross-sectional view of the column CL of the semiconductor device of the first embodiment. FIG. 2 corresponds to a cross section parallel to the Y-Z plane of FIG. 1. FIG. 2 shows an extracted portion on the upper end side of the column CL.

The column CL is provided in the stacked body 100. Drain-side selection gates SGDa to SGDc, the multiple word lines WL, and the multiple insulators 40 are exposed from an inner wall of a memory hole (a hole) MH provided in the stacked body 100. Thereby, the drain-side selection gates SGDa to SGDc and the word lines WL are provided around the periphery of the column CL. A memory film 30 that includes a charge storage portion is provided on the inner wall of the memory hole MH. The configuration of the memory film 30 is, for example, a cylindrical configuration. A semiconductor body 20 is provided on the memory film 30. The configuration of the semiconductor body 20 is, for example, a circular tube that has a bottom. A core layer 50 is provided on the semiconductor body 20. The core layer 50 is insulative. The configuration of the core layer 50 is, for example, a columnar configuration. The memory film 30, the semiconductor body 20, and the core layer 50 are filled into the interior of the memory hole MH.

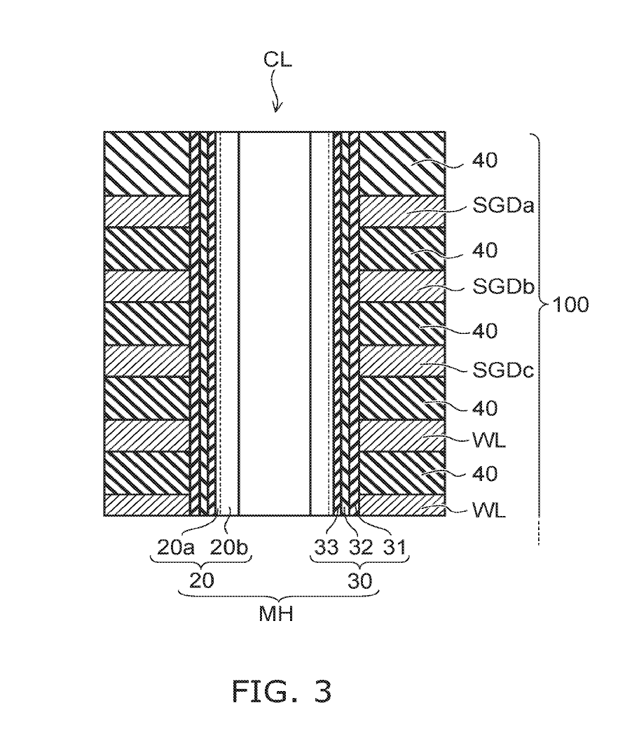

FIG. 3 is a schematic cross-sectional view of the semiconductor body 20 and the memory film 30. An example of the semiconductor body 20 and the memory film 30 is shown in FIG. 3.

As shown in FIG. 3, the memory film 30 includes a blocking insulating film 31, a charge storage film 32, and a tunneling insulating film 33. The blocking insulating film 31 is provided on the inner wall of the memory hole MH. The blocking insulating film 31 includes, for example, silicon oxide, or silicon oxide and aluminum oxide. The charge storage film 32 is provided on the blocking insulating film 31. The charge storage film 32 includes, for example, silicon nitride. Other than silicon nitride, the charge storage film 32 may include hafnium oxide. The tunneling insulating film 33 is provided on the charge storage film 32. The tunneling insulating film 33 includes, for example, silicon oxide, or silicon oxide and silicon nitride.

The charge storage film 32 includes trap sites that trap charge; and the charge storage film 32 traps charge. The threshold of the memory cell MC changes due to the existence or absence of the trapped charge and the amount of the trapped charge. Thereby, the memory cell MC retains information. The tunneling insulating film 33 is a potential barrier between the charge storage film 32 and the semiconductor body 20. Tunneling of the charge in the tunneling insulating film 33 occurs when the charge is injected from the semiconductor body 20 into the charge storage film 32 (the programming operation) and when the charge is caused to diffuse from the charge storage film 32 into the semiconductor body 20 (the erasing operation). The blocking insulating film 31 suppresses the back-tunneling of the charge from the word line WL into the charge storage film 32 in the erasing operation. In FIG. 3, the charge storage film 32 may be removed at the position where the drain-side selection gates SGDa to SGDc are formed. In that case, a film other than the memory film 30 may be formed as a gate insulating film of the drain-side selection transistor STD instead of the memory film 30 partly remaining at the position where the word line WL is formed.

The semiconductor body 20 includes a cover film 20a and a channel film 20b. The cover film 20a is provided on the tunneling insulating film 33. The channel film 20b is provided on the cover film 20a. For example, the cover film 20a and the channel film 20b are semiconductors of a first conductivity type. In a direction perpendicular to the stacking direction, the thickness of the cover film 20a is thinner than the thickness of the channel film 20b. The cover film 20a and the channel film 20b of the first embodiment are P-type polysilicon. The P-type polysilicon is, for example, P-type amorphous silicon that is crystallized. The cover film 20a and the channel film 20b include a P-type impurity as a carrier. The P-type impurity is, for example, boron. The concentration (the carrier concentration) of the boron of the semiconductor body 20 of the first embodiment is, for example, a finite value that is 1×10¹⁷ cm⁻³ or less. The semiconductor body 20 includes a substantially uniform concentration of boron having, for example, the finite value that is 1×10¹⁷ cm⁻³ or less from the upper end portion to the lower end portion of the memory hole MH.

As shown in FIG. 3, the semiconductor body 20 extends through the stacked body 100 in the stacking direction (the Z-direction) of the stacked body 100. As shown in FIG. 2, the semiconductor body 20 includes a first portion 21, a second portion 22, and a third portion 23 along the stacking direction of the stacked body 100 downward from the upper surface of the stacked body 100.

The second portion 22 is set to be between the first portion 21 and the third portion 23. A first semiconductor layer 24 of the first conductivity type is provided in the second portion 22. The first semiconductor layer 24 is provided in a ring configuration in the second portion 22. The first semiconductor layer 24 of the first embodiment is a P-type diffusion layer. A P-type impurity is diffused in the P-type diffusion layer. The P-type impurity is, for example, boron. The first semiconductor layer 24 of the first embodiment includes the same impurity as the P-type impurity included in the semiconductor body 20. The concentration (the carrier concentration) of the boron of the first semiconductor layer 24 is higher than the concentration of the boron of the third portion 23. The concentration of the boron of the first semiconductor layer 24 of the first embodiment is, for example, not less than 1×10¹⁸ cm⁻³ and not more than 5×10¹⁹ cm⁻³ at the peak value.

An insulating layer 60 is provided on a region 25 of the semiconductor body 20. The region 25 is the region of the first portion 21 including the terminal portion of the first semiconductor layer 24. The insulating layer 60 is, for example, an insulator having silicon nitride as a major component.

The core layer 50 includes a first core layer 51 and a second core layer 52. The second core layer 52 is provided on the third portion 23. The first core layer 51 is provided on the upper end portion of the second core layer 52 and on the second portion 22 and insulating layer 60 along the stacking direction of the stacked body 100. The first core layer 51 and the second core layer 52 are insulative. The first core layer 51 and the second core layer 52 are, for example, insulators having silicon oxide as a major component.

A second semiconductor layer 70 of a second conductivity type is on the first core layer 51. The second semiconductor layer 70 is provided on the first portion 21, the insulating layer 60, and the first core layer 51. The second semiconductor layer 70 contacts the first portion 21. The second semiconductor layer 70 is N-type polysilicon. The N-type polysilicon may be N-type amorphous silicon that is crystallized. The second semiconductor layer 70 includes an N-type impurity. The N-type impurity is, for example, arsenic or phosphorus. A third semiconductor layer 71 of the second conductivity type is provided in the first portion 21. For example, the third semiconductor layer 71 is formed by diffusing the N-type impurity from the second semiconductor layer 70 into the first portion 21.

An insulating film 75 is provided on the upper end portion of the stacked body 100. A contact hole 76 is provided in the insulating film 75. The contact hole 76 reaches the second semiconductor layer 70 and the third semiconductor layer 71. The contact Cb is provided in the contact hole 76. The contact Cb is electrically connected to the second semiconductor layer 70 and the third semiconductor layer 71.

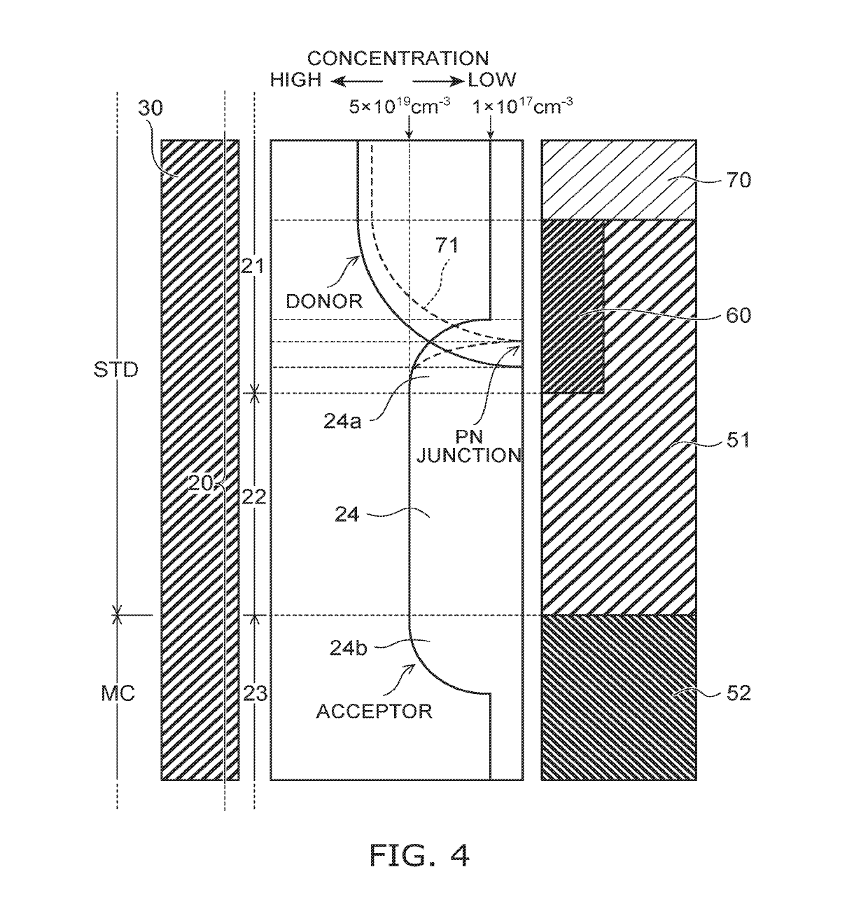

FIG. 4 is a figure showing the concentration profile of the impurities of the semiconductor body 20.

As shown in FIG. 4, the semiconductor body 20 includes an acceptor (a P-type carrier), e.g., boron, having a substantially uniform concentration of the finite value that is 1×10¹⁷ cm⁻³ or less in the first portion 21, the second portion 22, and the third portion 23. Thereby, the channel concentration of the memory cell MC is the finite value that is 1×10¹⁷ cm⁻³ or less.

The first semiconductor layer 24 is provided in the second portion 22. Therefore, the acceptor concentration (the P-type carrier concentration) of the second portion 22 exceeds the finite value that is 1×10¹⁷ cm⁻³ or less. For example, the concentration of the first semiconductor layer 24 is not less than 1×10¹⁸ cm⁻³ and not more than 5×10¹⁹ cm⁻³ at the peak value. Thereby, the channel concentration of the selection transistor STD exceeds the acceptor concentration of the semiconductor body 20 and is not more than 5×10¹⁹ cm⁻³ and more than the finite value that is 1×10¹⁷ cm⁻³ or less. Therefore, the threshold voltage Vth of the selection transistor STD can be high compared to the case where the value of the channel concentration of the selection transistor STD is the same as the acceptor concentration of the semiconductor body 20. Accordingly, according to the first embodiment, the off-leakage current of the selection transistor STD can be reduced.

The first portion 21 includes an acceptor having a concentration of the finite value that is 1×10¹⁷ cm⁻³ or less. Due to the manufacturing of the first portion 21 of the first embodiment, a region 24a in which the acceptor has diffused from the first semiconductor layer 24 exists in the first portion 21. The region 24a exists from the lower end portion of the insulating layer 60 to a portion of the insulating layer 60 above the lower end portion. The method for manufacturing the region 24a is described below. The acceptor concentration of the region 24a is not more than 5×10¹⁹ cm⁻³ and not less than the finite value that is 1×10¹⁷ cm⁻³ or less.

The third portion 23 includes an acceptor having a concentration of the finite value that is 1×10¹⁷ cm⁻³ or less. Due to the manufacturing of the third portion 23 of the first embodiment, a region 24b in which the acceptor has diffused from the first semiconductor layer 24 exists in the third portion 23 as well. The region 24b exists from the upper end portion of the second core layer 52 to a portion of the second core layer 52 below the upper end portion. The acceptor concentration of the region 24b is not more than 5×10¹⁹ cm⁻³ and not less than the finite value that is 1×10¹⁷ cm⁻³ or less.

In addition to the acceptor, the first portion 21 includes a donor (an N-type carrier), e.g., arsenic or phosphorus. The donor concentration (the N-type carrier concentration) of the first portion 21 exceeds the finite value that is 1×10¹⁷ cm⁻³ or less. Thereby, the third semiconductor layer 71 is provided in the first portion 21. The effective carrier concentration of the third semiconductor layer 71 can be expressed by

effective carrier concentration=donor concentration−acceptor concentration.

The acceptor concentration of the first portion 21 of the first embodiment is the acceptor concentration of the semiconductor body 20. For example, the acceptor concentration of the first portion 21 is low compared to the case where the first semiconductor layer 24 is provided in the entire first portion 21. Therefore, the third semiconductor layer 71 that has a high effective carrier concentration can be obtained in the first portion 21. The third semiconductor layer 71 is a drain of the selection transistor STD. Accordingly, according to the first embodiment, the selection transistor STD that has a low drain resistance can be obtained.

A P-N junction between the first semiconductor layer 24 and the third semiconductor layer 71 is provided in the first portion 21. In the first embodiment, the insulating layer 60 is provided between the P-N junction and the first core layer 51. In the first embodiment, the P-N junction does not directly contact the first core layer 51. Therefore, compared to the case where the insulating layer 60 on the first portion 21 is removed, the occurrence of sites in the first portion 21 such as crystal defects, etc., that cause a leakage current can be suppressed. The third semiconductor layer 71 is the drain of the selection transistor STD. The first semiconductor layer 24 is the channel of the selection transistor STD. Accordingly, according to the first embodiment, the leakage current that is generated from the P-N junction between the channel and the drain when the channel and the drain are in a reverse bias state can be reduced.

Thus, according to the first embodiment, the threshold voltage Vth of the selection transistor STD can be increased. Accordingly, the selection transistor STD having a small off-leakage current can be obtained.

Also, according to the first embodiment, the carrier concentration (the effective carrier concentration) of the drain of the selection transistor STD can be increased. Accordingly, the selection transistor STD having a low drain resistance can be obtained.

Further, according to the first embodiment, the occurrence of sites of the first portion 21 that cause a leakage current can be suppressed. Accordingly, the selection transistor STD that has a small leakage current from the P-N junction between the channel and the drain when the channel and the drain are in the reverse bias state can be obtained.

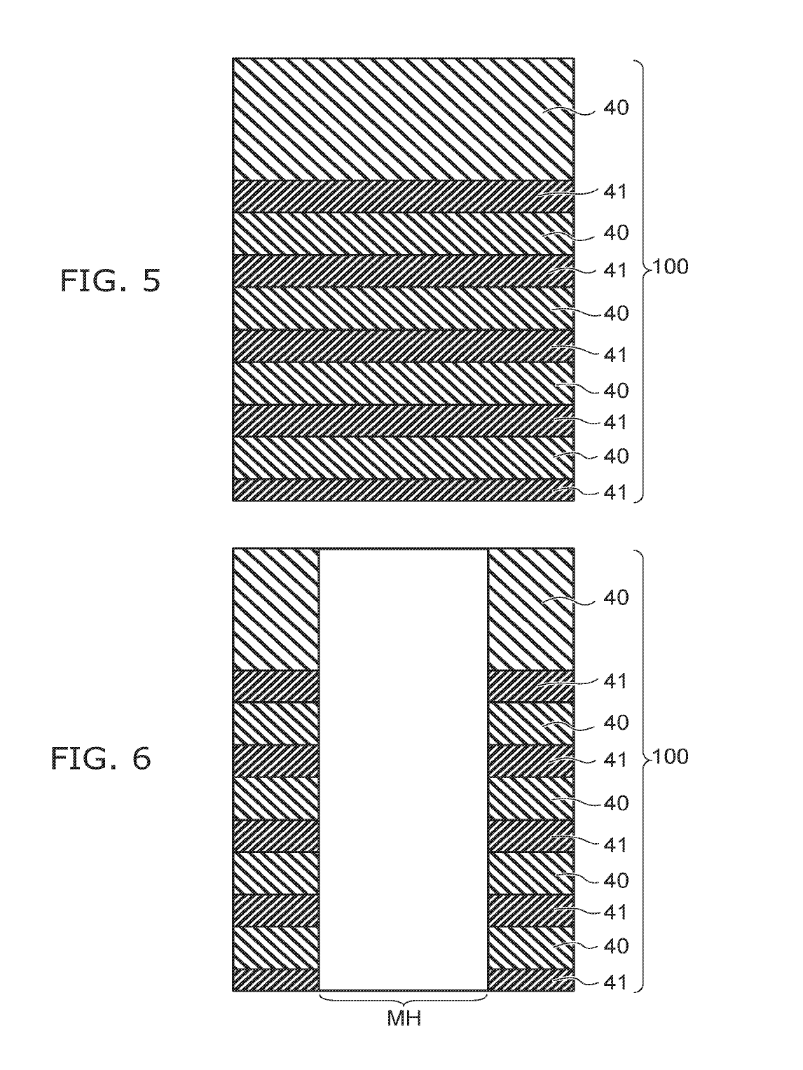

FIG. 5 to FIG. 18 are schematic cross-sectional views showing a method for manufacturing the semiconductor device of the first embodiment. The cross sections shown in FIG. 5 to FIG. 18 correspond to the cross section shown in FIG. 2.

As shown in FIG. 5, the stacked body 100 is formed on the substrate 10 by stacking the insulators 40 as first layers and replacement members 41 as second layers alternately on the substrate 10 (not shown in FIG. 5). The replacement members 41 are layers that are replaced with the electrode layers (SGD, WL, and SGS) subsequently. The material of the replacement members 41 is selected from materials that are different from the insulators 40 and can provide etching selectivity with respect to the insulators 40. For example, silicon nitride is selected as the replacement members 41 in the case where silicon oxide is selected as the insulators 40.

Then, as shown in FIG. 6, the memory hole MH is made in the stacked body 100 using, for example, photolithography.

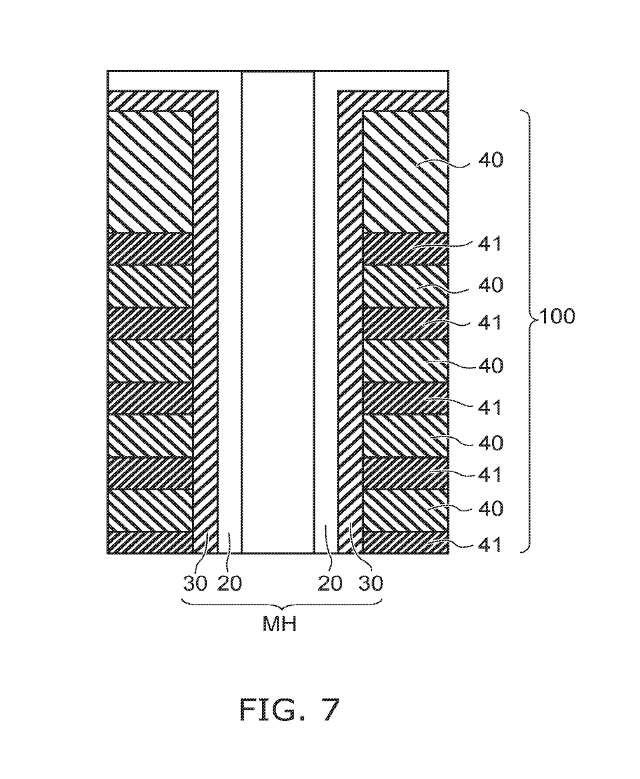

Then, as shown in FIG. 7, the memory film 30 is formed on the stacked body 100 and on the inner wall of the memory hole MH. For example, as shown in FIG. 3, the memory film 30 is formed in the order of the blocking insulating film 31, the charge storage film 32, and the tunneling insulating film 33 from the inner wall side of the memory hole MH. For example, the blocking insulating film 31 is formed by depositing silicon oxide, or silicon oxide and aluminum oxide, on the stacked body 100 and on the inner wall of the memory hole MH. For example, the charge storage film 32 is formed by depositing silicon nitride on the blocking insulating film 31. The tunneling insulating film 33 is formed by depositing silicon oxide, or silicon oxide and silicon nitride, on the charge storage film 32.

Then, the semiconductor body 20 is formed on the memory film 30. As shown in FIG. 3, the semiconductor body 20 is formed by depositing the semiconductor body 20 in the order of the cover film 20a and the channel film 20b on the memory film 30. For example, the cover film 20a is formed by depositing silicon doped with boron on the tunneling insulating film 33. Although not shown in FIG. 7, the cover film 20a and the memory film 30 that exist on the bottom of the memory hole MH are removed after forming the cover film 20a. Thereby, the substrate 10 is exposed at the bottom of the memory hole MH. Then, for example, silicon doped with boron is deposited on the cover film 20a and on the substrate 10 exposed at the bottom of the memory hole MH. Thereby, the channel film 20b is formed on the cover film 20a and on the substrate 10 exposed at the bottom of the memory hole MH. The channel film 20b is electrically connected to the substrate 10. The cover film 20a and the channel film 20b are, for example, amorphous. Subsequently, crystallization annealing of the cover film 20a and the channel film 20b is performed. Thereby, the cover film 20a and the channel film 20b are crystallized; and the P-type semiconductor body 20 is formed. It is sufficient for the crystallization annealing to be performed after the cover film 20a and the channel film 20b are formed. The timing of the crystallization annealing is not limited to the timing of the first embodiment.

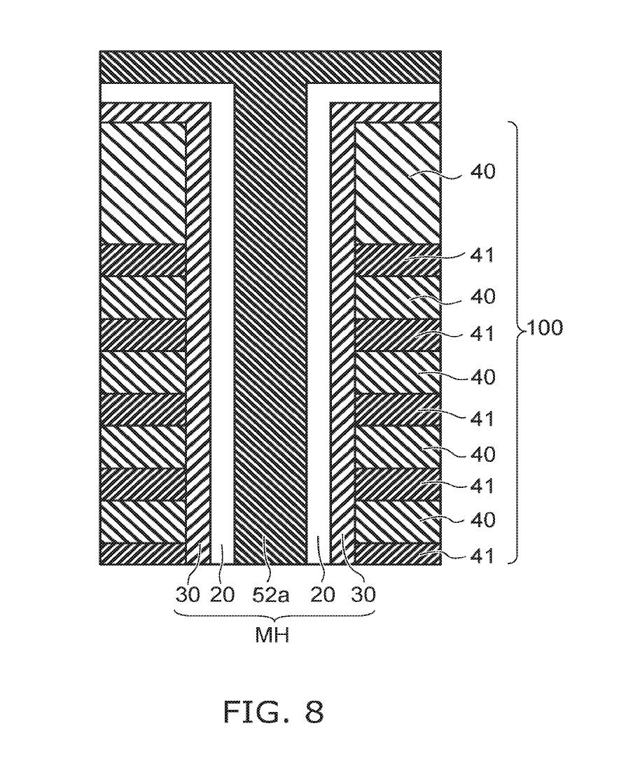

Then, as shown in FIG. 8, an insulator, e.g., silicon oxide 52a, is deposited on the semiconductor body 20. Thereby, the memory hole MH is filled with the silicon oxide 52a.

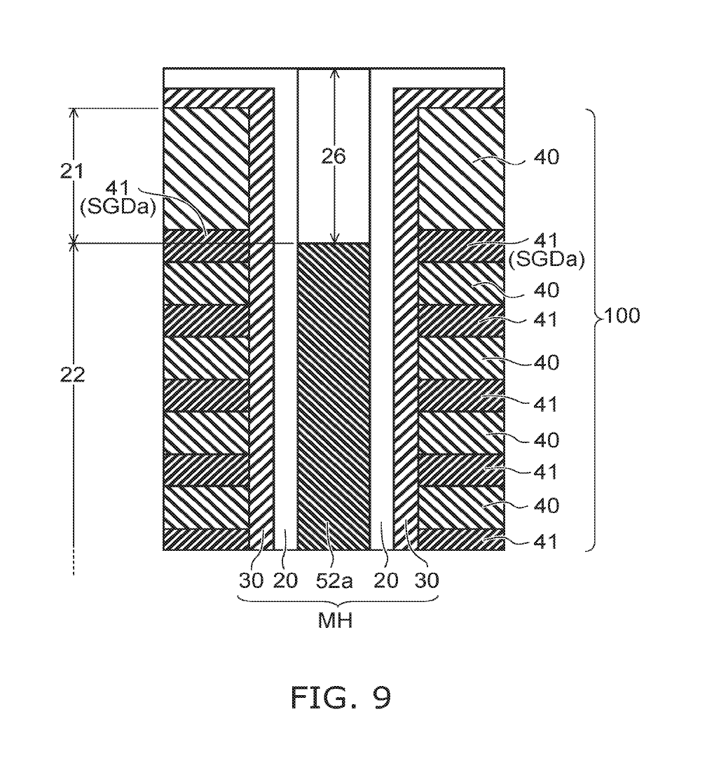

Then, as shown in FIG. 9, the surface of the silicon oxide 52a is caused to recede into the interior of the memory hole MH. Thereby, a first recessed portion 26 where the surface of the semiconductor body 20 is exposed is formed in the interior of the memory hole MH. The first recessed portion 26 is formed to obtain the boundary between the first portion 21 and the second portion 22 in the semiconductor body 20. In the first embodiment, the depth of the first recessed portion 26 (the receded amount of the silicon oxide 52a) is set to be the position where the drain-side selection gate SGDa of the uppermost layer is formed so that the second portion 22 is formed to include the region used to form the channel of the drain-side selection transistor STD. Thereby, in the first embodiment, the boundary between the first portion 21 and the second portion 22 is set to be at the position where the selection gate SGDa is formed. For example, the boundary between the first portion 21 and the second portion 22 is not limited to that of the first embodiment and may be set to be at the boundary position between the selection gate SGDa and the insulator 40 of the upper layer or at the position where the insulator 40 of the upper layer is formed.

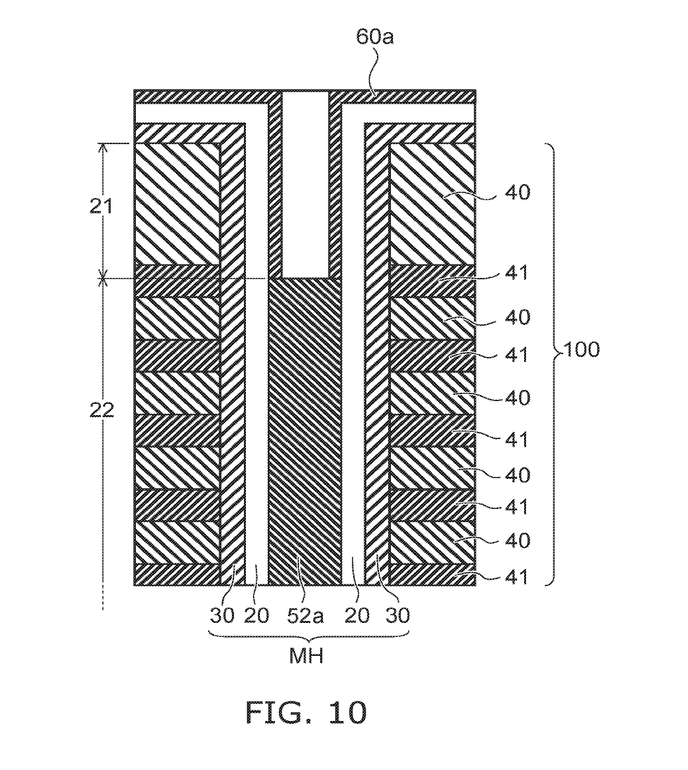

Then, as shown in FIG. 10, the exposed surface of the semiconductor body 20 is nitrided. Thereby, silicon nitride 60a is formed on the semiconductor body 20. The silicon nitride 60a has a different composition than the silicon oxide 52a.

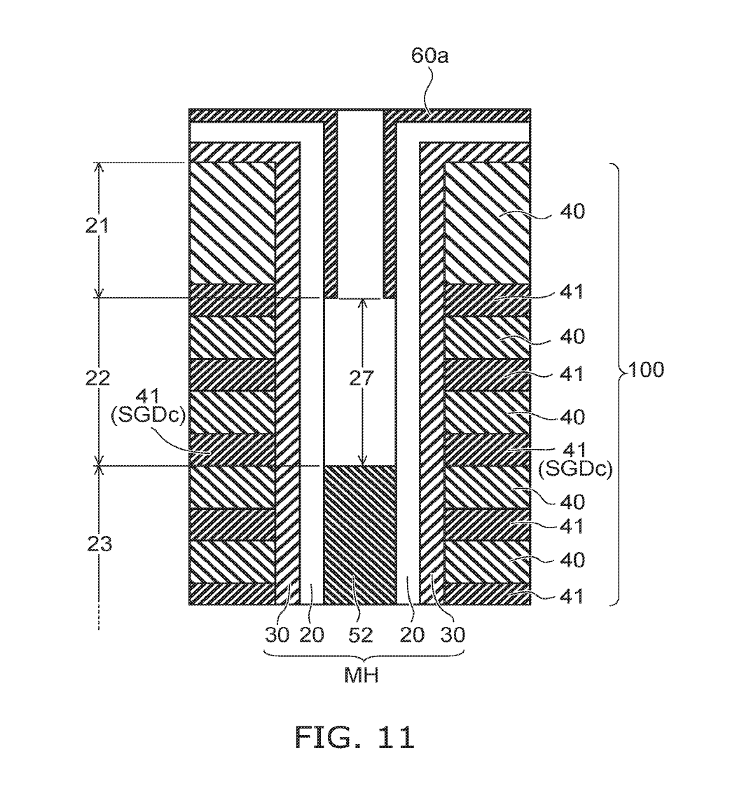

Then, as shown in FIG. 11, the surface of the silicon oxide 52a is caused to recede further into the interior of the memory hole MH by using the silicon nitride 60a as a mask. Thereby, a second recessed portion 27 where the surface of the semiconductor body 20 is exposed is formed in the interior of the memory hole MH. The second recessed portion 27 is formed to obtain the boundary between the second portion 22 and the third portion 23 in the semiconductor body 20. In the first embodiment, the depth of the second recessed portion 27 (the receded amount of the silicon oxide 52a) is set to be at the boundary position between the drain-side selection gate SGDc of the lowermost layer and the insulator 40 of the lower layer so that the third portion 23 is formed to include the region used to form the channel of the memory cell MC. Thereby, in the first embodiment, the boundary between the second portion 22 and the third portion 23 is set to be at the boundary position between the selection gate SGDc and the insulator 40 of the lower layer. The boundary between the second portion 22 and the third portion 23 is not limited to the first embodiment and may be, for example, set to be at the position where the selection gate SGDc is formed or at the position where the insulator 40 of the lower layer is formed. Also, the silicon oxide 52a is used to form the second core layer 52.

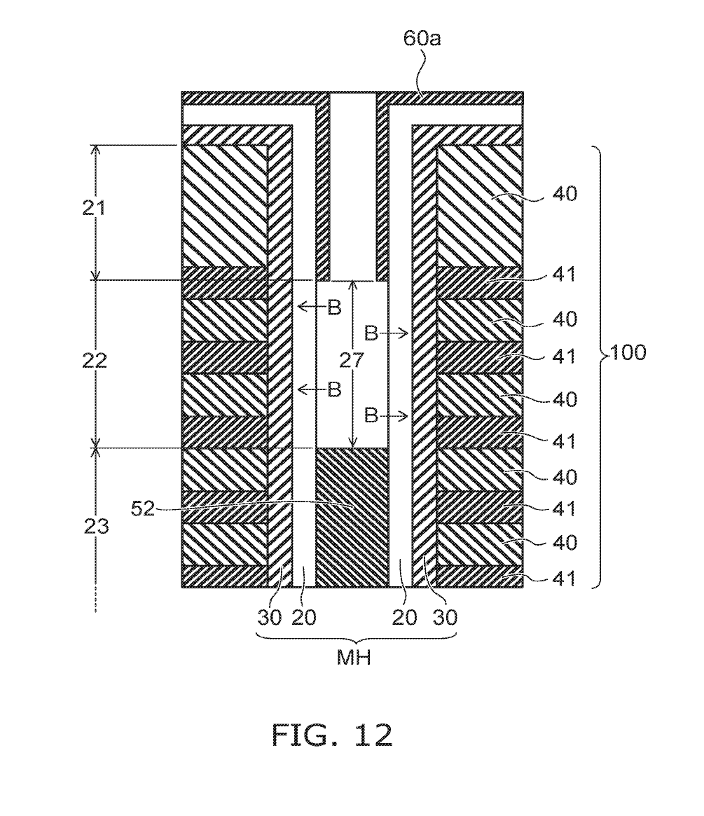

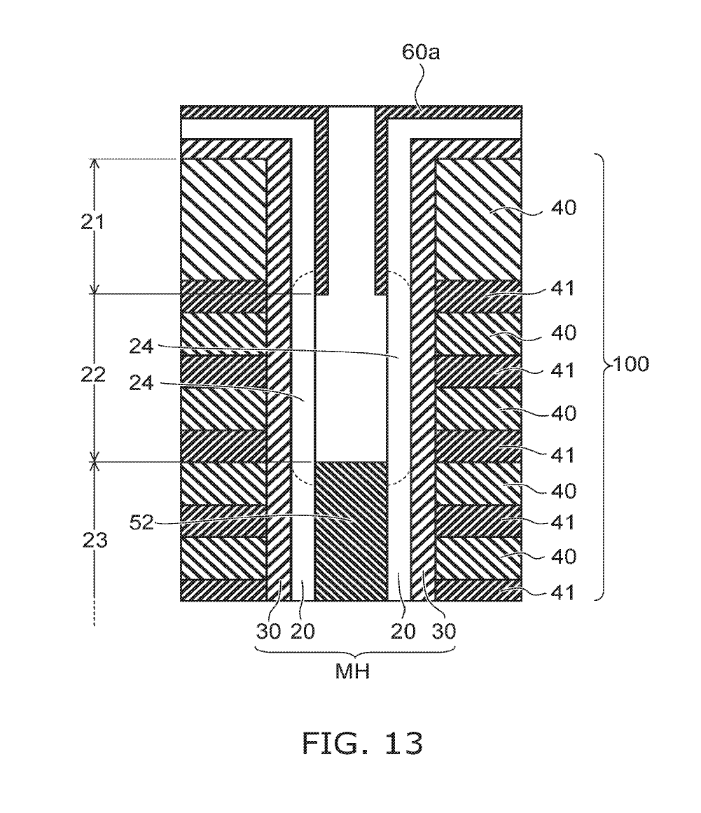

Then, as shown in FIG. 12, the P-type impurity is introduced to the interior of the semiconductor body 20 using the silicon nitride 60a and the second core layer 52 as a mask for impurity introduction. The P-type impurity is boron (B). To introduce the boron (B), vapor phase diffusion may be used; or solid state diffusion may be used. In the case of vapor phase diffusion, for example, it is sufficient to cause a boron-containing gas to flow onto the exposed surface of the semiconductor body 20. In the case of solid state diffusion, for example, it is sufficient to form a boron-containing film on the exposed surface of the semiconductor body 20. Thereby, as shown in FIG. 13, the first semiconductor layer 24 is formed in the second portion 22 of the semiconductor body 20.

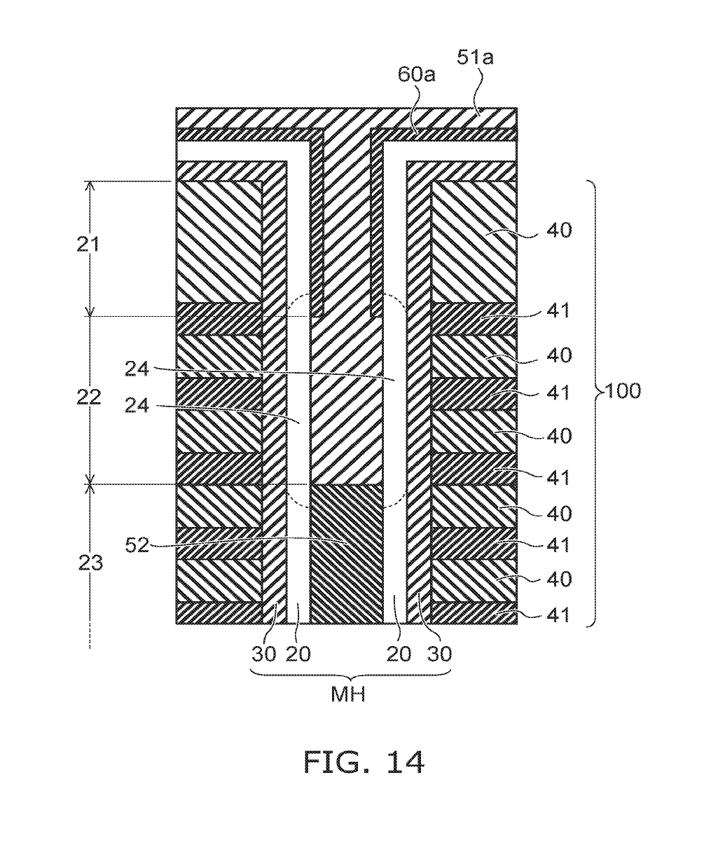

Then, as shown in FIG. 14, an insulator, e.g., silicon oxide 51a, is deposited on the second core layer 52, the semiconductor body 20, and the silicon nitride 60a. Thereby, the memory hole MH is filled with the silicon oxide 51a.

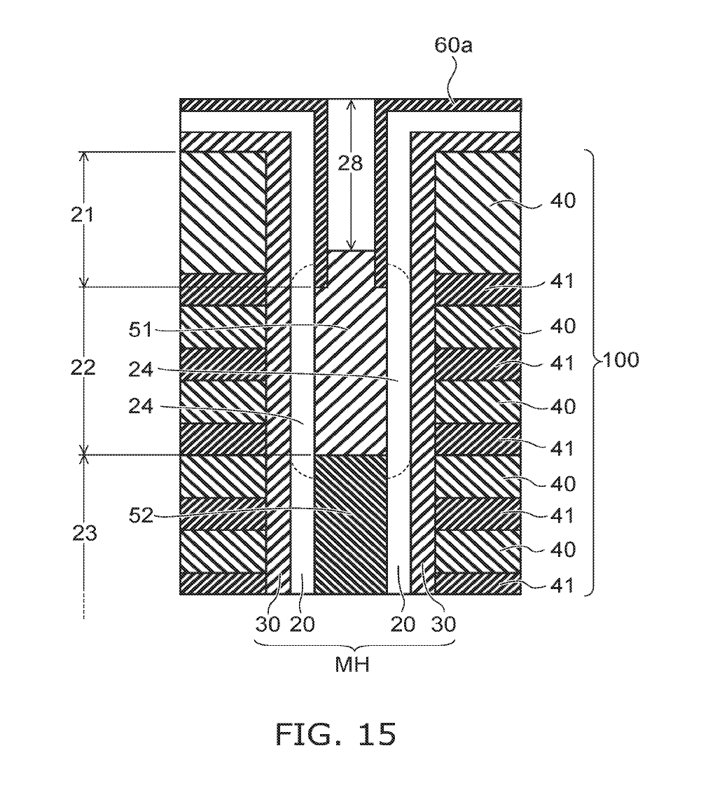

Then, as shown in FIG. 15, the surface of the silicon oxide 51a is caused to recede into the interior of the memory hole MH. Thereby, a third recessed portion 28 where the surface of the silicon nitride 60a is exposed is formed in the interior of the memory hole MH. The third recessed portion 28 is formed to obtain the region where the second semiconductor layer 70 is formed in the interior of the memory hole MH. Also, the silicon oxide 51a is used to form the first core layer 51.

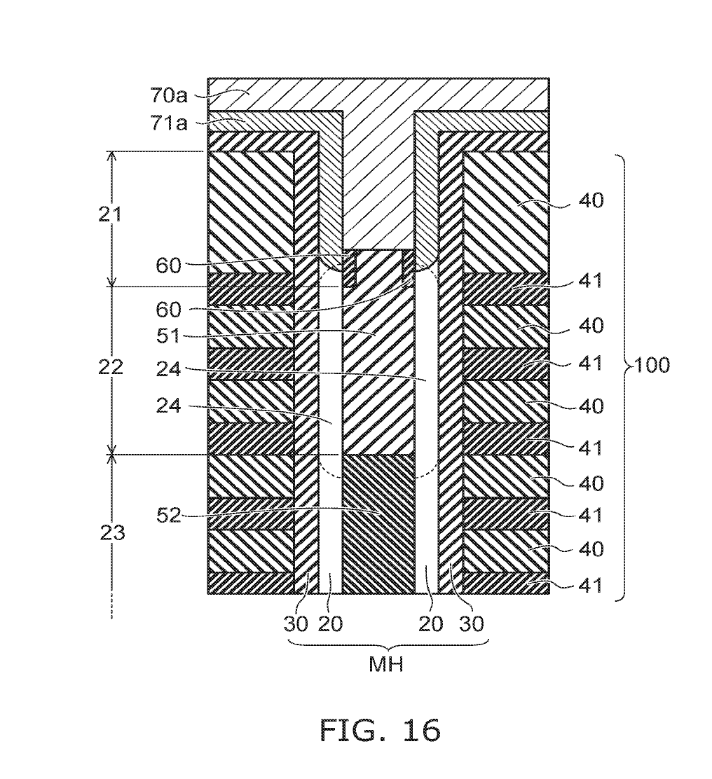

Then, as shown in FIG. 16, the silicon nitride 60a is etched using the semiconductor body 20 and the first core layer 51 as a mask. Thereby, the insulating layer 60 is formed in the interior of the memory hole MH. Then, silicon that is doped with arsenic or phosphorus is deposited on the semiconductor body 20, the first core layer 51, and the insulating layer 60. The interior of the memory hole MH is filled with N-type silicon 70a. The N-type silicon 70a is, for example, amorphous. Then, crystallization annealing of the N-type silicon 70a is performed. Thereby, the N-type silicon 70a is crystallized. Also, the arsenic or the phosphorus diffuses in the semiconductor body 20 in the crystallization annealing. Thereby, an N-type diffusion layer 71a is formed in the semiconductor body 20.

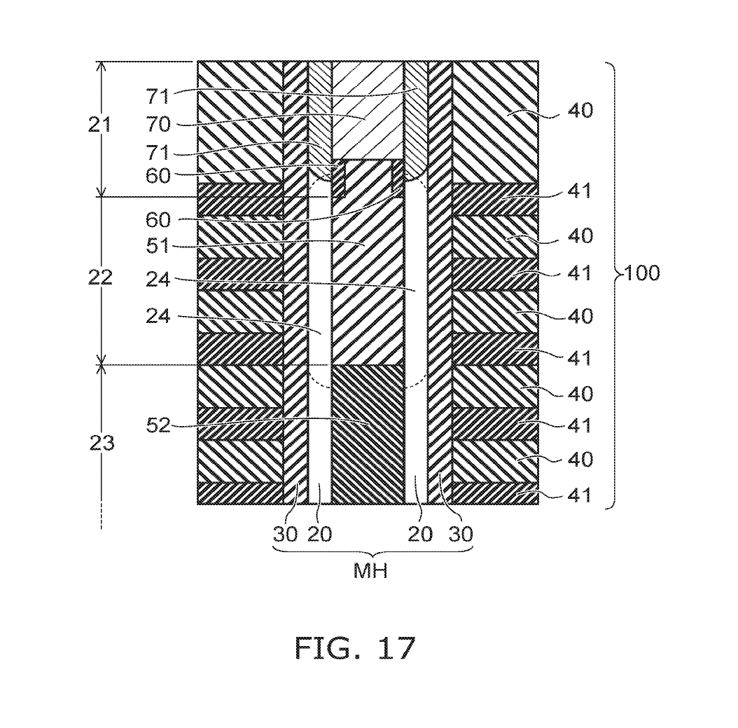

Then, as shown in FIG. 17, the N-type silicon 70a, the N-type diffusion layer 71a, and the memory film 30 are caused to recede to the upper end portion of the stacked body 100. Thereby, the second semiconductor layer 70 and the third semiconductor layer 71 are formed in the interior of the memory hole MH.

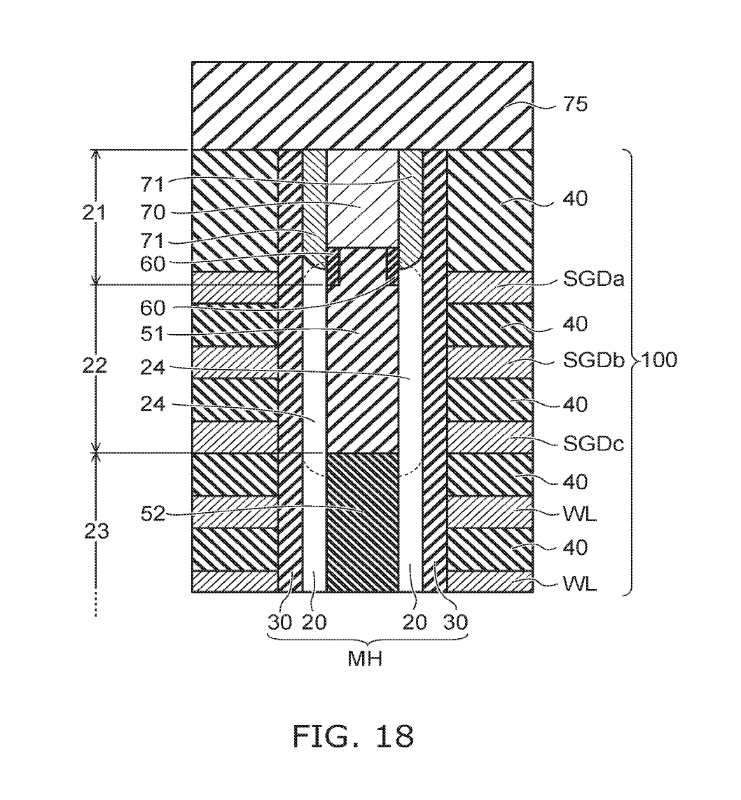

Then, as shown in FIG. 18, the insulating film 75 is formed on the stacked body 100, the second semiconductor layer 70, and the third semiconductor layer 71. The separation portions ST shown in FIG. 1 are made in the insulating film 75 and the stacked body 100. Then, the replacement members 41 are removed via the separation portions ST. Then, the portions where the replacement members 41 are removed are filled with a conductor. Thereby, the multiple electrode layers (SGDa to SGDc and WL) are formed between the insulators 40.

Then, as shown in FIG. 2, the contact hole 76 is made in the insulating film 75. The contact hole 76 reaches the second semiconductor layer 70 and the third semiconductor layer 71. Then, the contact hole 76 is filled with the contact Cb. Thereby, the semiconductor device according to the first embodiment is fabricated.

For example, the semiconductor device of the first embodiment can be manufactured by such a manufacturing method.

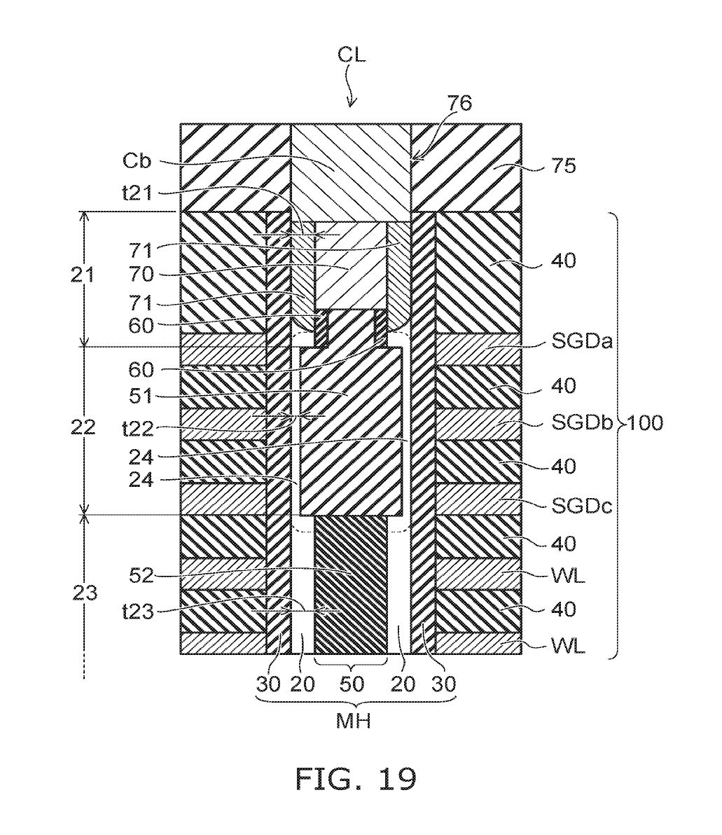

FIG. 19 is a schematic cross-sectional view of the column CL of a semiconductor device of a second embodiment. The cross section shown in FIG. 19 corresponds to the cross section shown in FIG. 2.

As shown in FIG. 19, the configuration of the second portion 22 of the second embodiment is different from that of the first embodiment shown in FIG. 2. In the second embodiment, a thickness t22 of the second portion 22 is thinner than a thickness t23 of the third portion 23 (t22<t23) in a direction perpendicular to the stacking direction of the stacked body 100.

Further, in the second embodiment, the thickness t22 of the second portion 22 is thinner than a thickness t21 of the first portion 21 (t22<t21) in a direction perpendicular to the stacking direction of the stacked body 100.

Also, in the example shown in FIG. 19, the thickness t21 of the first portion 21 is substantially equal to the thickness t23 of the third portion 23 (t21≈t23).

For such a second embodiment, compared to the first embodiment, the energy levels that trap charge in the channel (the second portion 22) of the selection transistor STD can be reduced. This is because the thickness t22 of the second portion 22 is thinner than the thickness t21 of the first portion 21 and the thickness t23 of the third portion 23. Therefore, compared to the first embodiment, for example, the off-leakage current that is generated via the energy levels can be reduced further.

Also, an off-leakage current is generated easily at a deep location of the channel distal to the selection gates SGDa to SGDc. This is because the potential from the selection gates SGDa to SGDc does not reach the deep location easily. The thickness t22 of the second portion 22 (the channel) of the second embodiment is thin compared to that of the first embodiment. Therefore, the potential of the selection gates SGDa to SGDc can reach the deep location of the channel. Accordingly, the off-leakage current that is generated at the deep location of the channel can be reduced.

Thus, according to the second embodiment, compared to the first embodiment, the electrical characteristics, e.g., the off-leakage characteristics, of the selection transistor STD can be improved further.

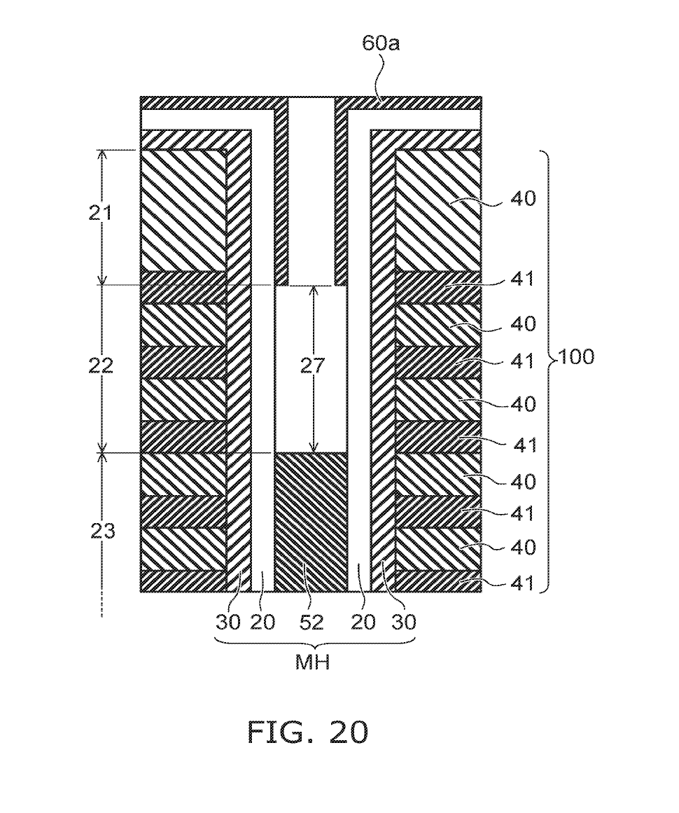

FIG. 20 to FIG. 22 are schematic cross-sectional views showing a method for manufacturing the semiconductor device of the second embodiment. The cross sections shown in FIG. 20 to FIG. 22 correspond to the cross section shown in FIG. 19.

As shown in FIG. 20, for example, the second recessed portion 27 is formed in the interior of the memory hole MH according to the manufacturing method described with reference to FIG. 5 to FIG. 11.

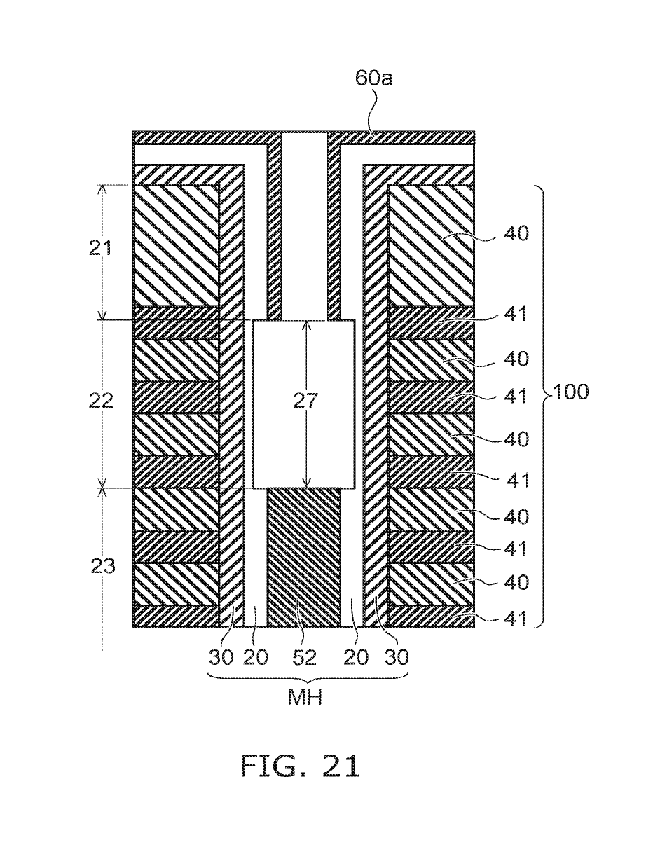

Then, as shown in FIG. 21, the semiconductor body 20 is etched using the silicon nitride 60a and the second core layer 52 as a mask of the etching. Thereby, the thickness of the second portion 22 is set to be thin compared to the first portion 21 and the third portion 23 in a direction perpendicular to the stacking direction of the stacked body 100.

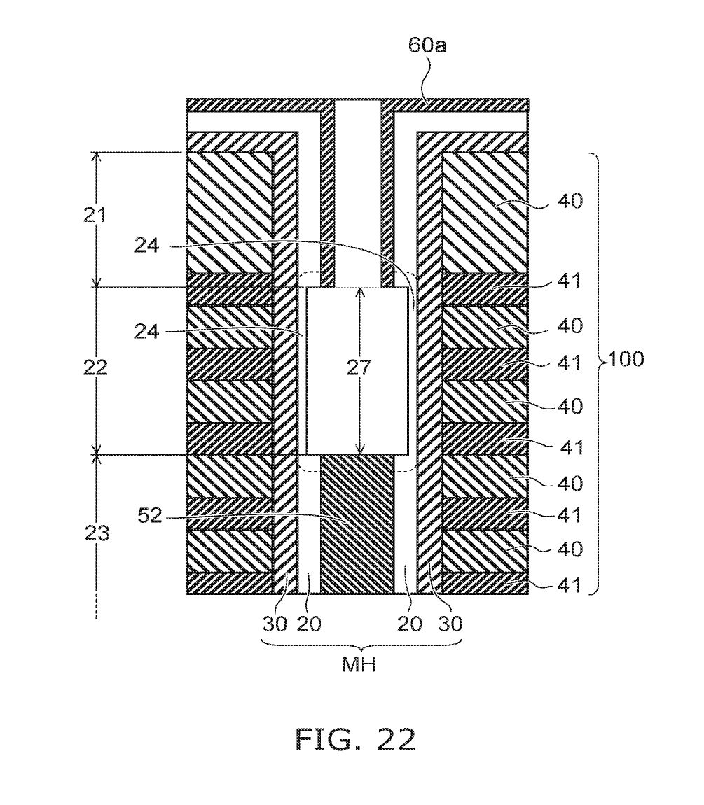

Then, as shown in FIG. 22, a P-type impurity, e.g., boron, is introduced to the interior of the semiconductor body 20 using the silicon nitride 60a and the second core layer 52 as a mask for impurity introduction. Thereby, the first semiconductor layer 24 is formed in the second portion 22 of the semiconductor body 20.

Thereafter, for example, the manufacturing method may be according to the manufacturing method described with reference to FIG. 14 to FIG. 18 and FIG. 2.

For example, the semiconductor device of the second embodiment can be manufactured by such a manufacturing method.

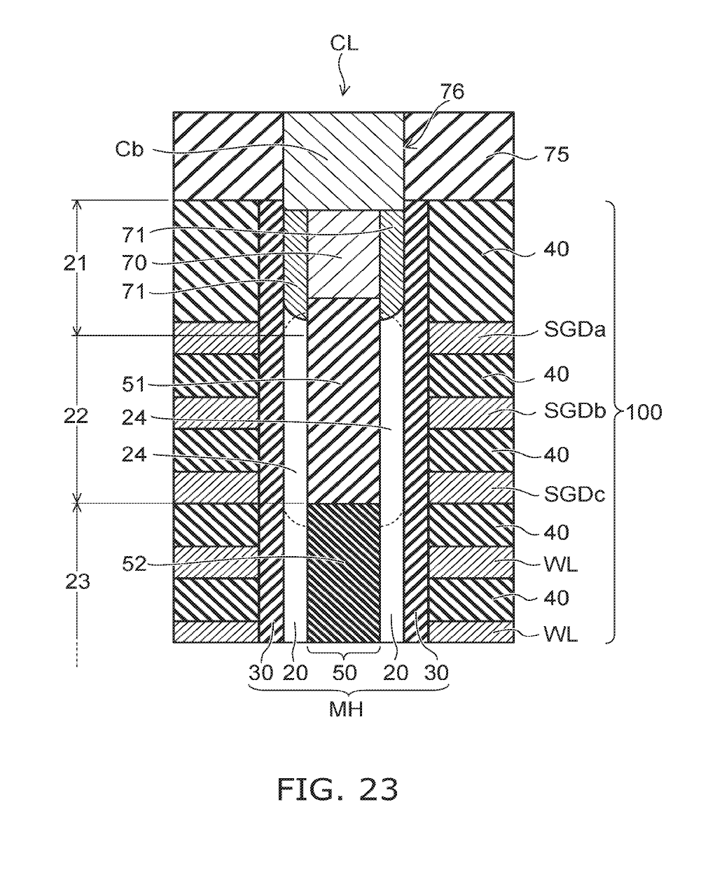

FIG. 23 is a schematic cross-sectional view of the column CL of a semiconductor device of a third embodiment. The cross section shown in FIG. 23 corresponds to the cross section shown in FIG. 2.

As shown in FIG. 23, the third embodiment differs from the first embodiment shown in FIG. 2 in that there is no insulating layer 60 on the semiconductor body 20. In the third embodiment, the first core layer 51 is provided on the first portion 21. The insulating layer 60 that is on the semiconductor body 20 may be removed.

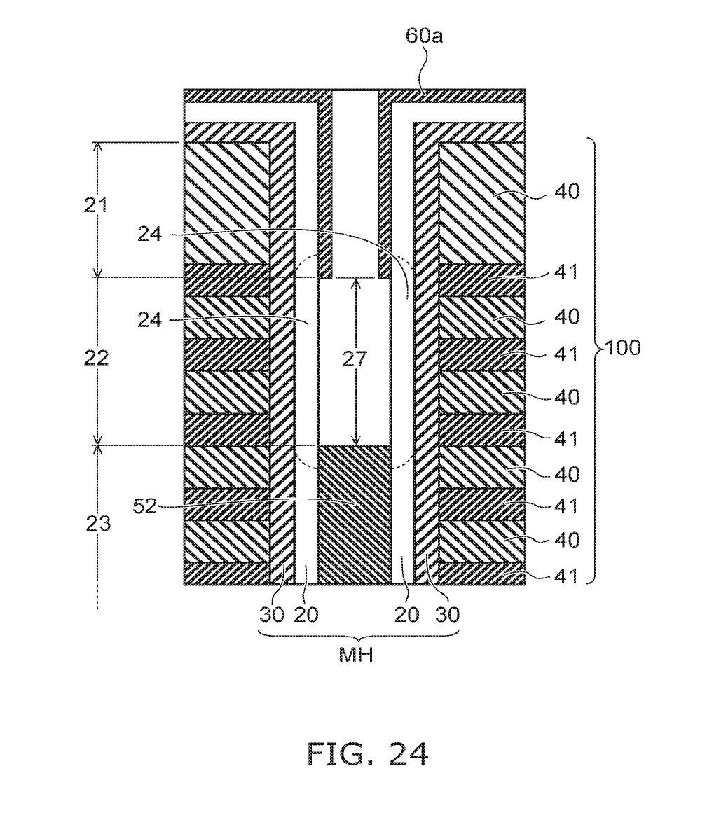

FIG. 24 to FIG. 26 are schematic cross-sectional views showing a method for manufacturing the semiconductor device of the third embodiment. The cross sections shown in FIG. 24 to FIG. 26 correspond to the cross section shown in FIG. 23.

As shown in FIG. 24, for example, the first semiconductor layer 24 is formed in the second portion 22 of the semiconductor body 20 according to the manufacturing method described with reference to FIG. 5 to FIG. 13.

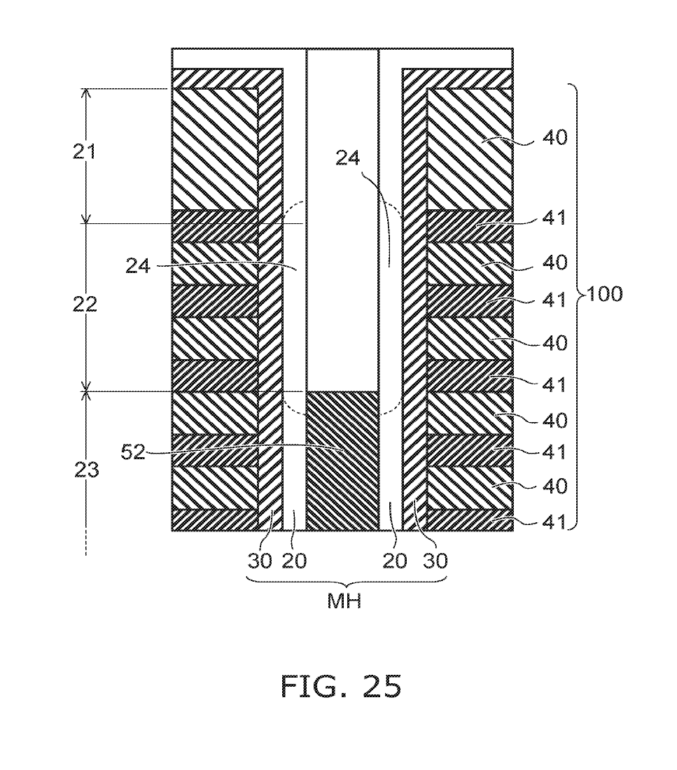

Then, as shown in FIG. 25, the silicon nitride 60a that is on the semiconductor body 20 is removed.

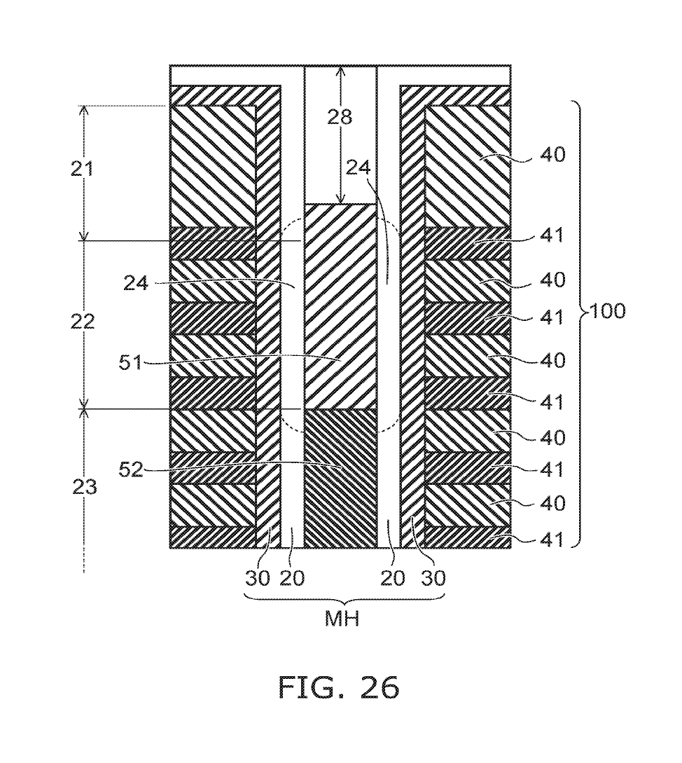

Then, as shown in FIG. 26, an insulator, e.g., silicon oxide, is deposited on the second core layer 52 and the semiconductor body 20. Thereby, the memory hole MH is filled with silicon oxide. Then, the surface of the silicon oxide is caused to recede into the interior of the memory hole MH. Thereby, the third recessed portion 28 and the first core layer 51 are formed in the interior of the memory hole MH.

Thereafter, for example, it is sufficient for the method for manufacturing to be according to the manufacturing method described with reference to FIG. 16 to FIG. 18 and FIG. 2.

For example, the semiconductor device of the third embodiment can be manufactured by such a manufacturing method.

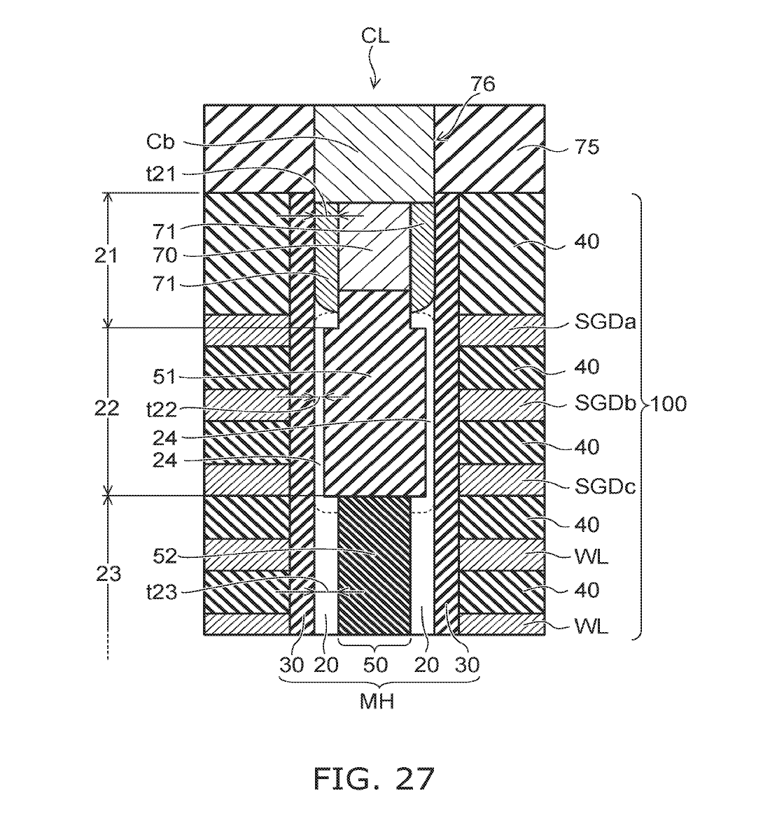

FIG. 27 is a schematic cross-sectional view of the column CL of a semiconductor device of a fourth embodiment. The cross section shown in FIG. 27 corresponds to the cross section shown in FIG. 19.

As shown in FIG. 27, the fourth embodiment differs from the second embodiment shown in FIG. 19 in that there is no insulating layer 60 on the semiconductor body 20. In the fourth embodiment as well, similarly to the third embodiment, the first core layer 51 is provided on the first portion 21. As in the fourth embodiment, in the semiconductor device of the second embodiment as well, the insulating layer 60 that is on the semiconductor body 20 may be removed.

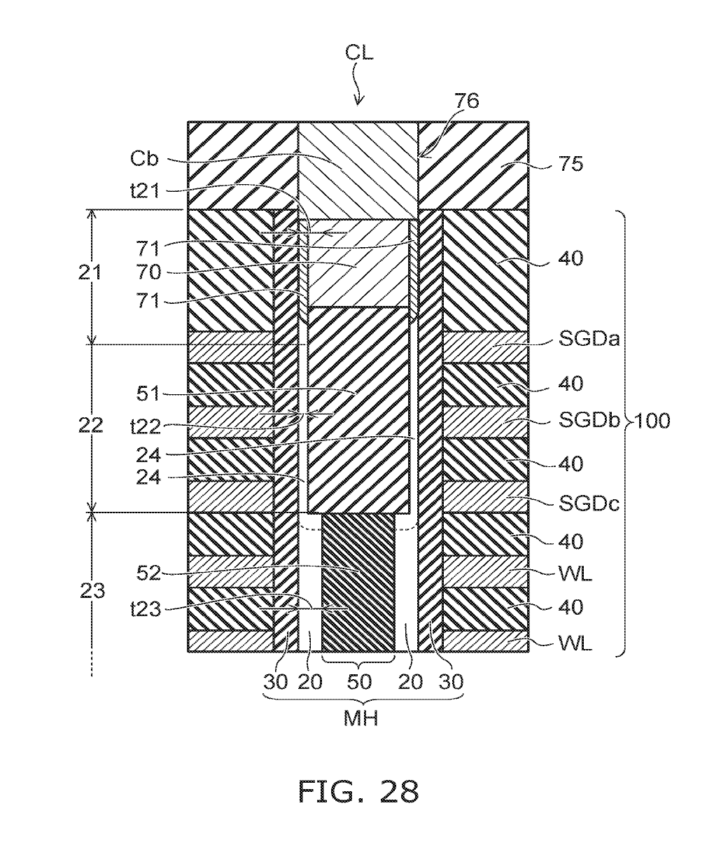

FIG. 28 is a schematic cross-sectional view of the column CL of a semiconductor device of a fifth embodiment.

The cross section shown in FIG. 28 corresponds to the cross section shown in FIG. 27.

As shown in FIG. 28, the configuration of the first portion 21 of the fifth embodiment is different from that of the fourth embodiment shown in FIG. 27. In the fifth embodiment, the thickness t21 of the first portion 21 is thinner than the thickness t23 of the third portion 23 (t21<t23) in a direction perpendicular to the stacking direction of the stacked body 100.

As in the fifth embodiment, the thickness t21 of the first portion 21 may be thinner than the thickness t23 of the third portion 23. In such a case, for example, the thickness t21 of the first portion 21 can be substantially equal to the thickness t22 of the second portion 22 (t21≈t22).

In the fifth embodiment as well, the thickness t22 of the second portion 22 is thinner than the thickness t23 of the third portion 23. Therefore, the energy levels that trap charge in the second portion 22 can be reduced compared to the first embodiment. Accordingly, compared to the first embodiment, the off-leakage current that is generated via the energy levels can be reduced.

Also, the thickness t22 of the second portion 22 (the channel) of the fifth embodiment is thin compared to that of the first embodiment. Accordingly, compared to the first embodiment, the off-leakage current that is generated at the deep location of the channel can be reduced.

According to the fifth embodiment, compared to the first embodiment, the electrical characteristics, e.g., the off-leakage characteristics, of the selection transistor STD can be improved further.

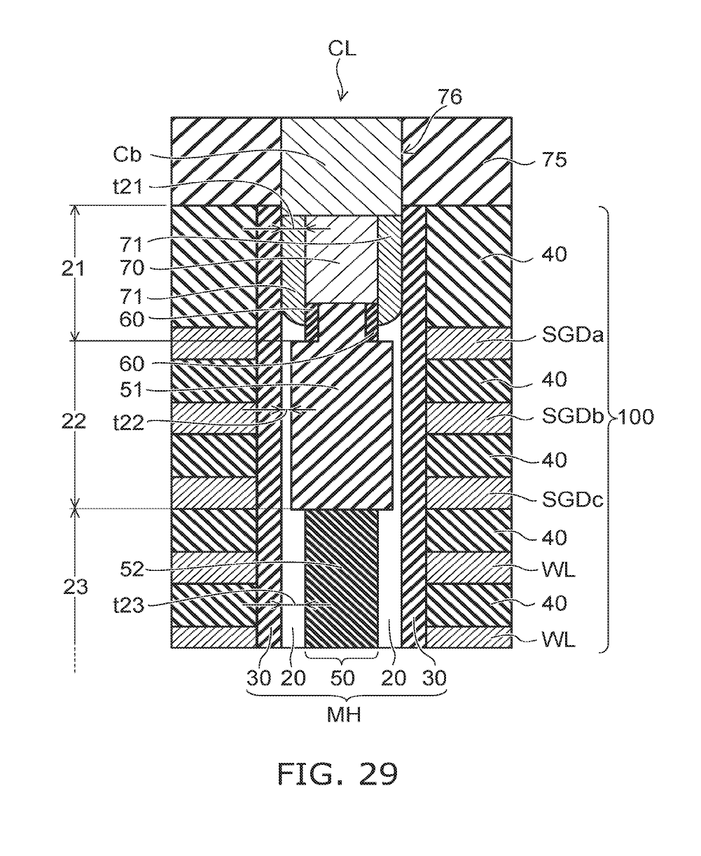

FIG. 29 is a schematic cross-sectional view of the column CL of a semiconductor device of a sixth embodiment. The cross section shown in FIG. 29 corresponds to the cross section shown in FIG. 19.

As shown in FIG. 29, the sixth embodiment differs from the second embodiment shown in FIG. 19 in that there is no first semiconductor layer 24 in the semiconductor body 20. In the sixth embodiment, for example, the semiconductor body 20 has a substantially uniform carrier concentration in the first portion 21, the second portion 22, and the third portion 23. In the sixth embodiment, the carrier concentration of the semiconductor body 20 is, for example, the finite value that is 1×10¹⁷ cm⁻³ or less. The semiconductor body 20 is, for example, the P-type and includes, for example, boron as the P-type carrier.

According to the sixth embodiment, the thickness t22 of the second portion 22 is thinner than the thickness t23 of the third portion 23. Therefore, compared to the case where the thickness t22 of the second portion 22 is substantially equal to the thickness t23 of the third portion 23, the energy levels that trap charge in the second portion 22 can be reduced. Accordingly, the off-leakage current that is generated via the energy levels can be reduced.

Also, the potential of the selection gates SGDa to SGDc reaches the deep location of the second portion 22 (the channel) because the thickness t22 of the second portion 22 is thinner than the thickness t23 of the third portion 23. Accordingly, the off-leakage current that is generated at the deep location of the channel can be reduced.

Further, the thickness t21 of the first portion 21 is thicker than the thickness t22 of the second portion 22 (t21>t22). Therefore, compared to the case where the thickness t21 is equal to the thickness t22 (t21=t22), excessive diffusion of the carrier, e.g., arsenic or phosphorus, from the second semiconductor layer 70 toward the second portion 22 of the semiconductor body 20 is suppressed. As a result, excessive overlap between the third semiconductor layer 71 and, for example, the drain-side selection gate SGDa of the uppermost layer is suppressed. The excessive overlap between the third semiconductor layer 71 and the selection gate SGDa causes the leakage current of the drain-side selection transistor STD to increase.

Accordingly, according to the embodiments in which the thickness t21 of the first portion 21 is thicker than the thickness t22 of the second portion (t21>t22), the leakage current of the selection transistor STD can be reduced further.

Thus, according to the embodiments, the increase of the off-leakage current generated in the selection transistor can be suppressed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a stacked body including a plurality of electrode layers stacked with an insulator interposed;
a semiconductor body of a first conductivity type extending through the stacked body in a stacking direction of the stacked body, the semiconductor body including, along the stacking direction of the stacked body, a first portion, a second portion, and a third portion, the second portion being provided between the first portion and the third portion;
a memory film provided between the semiconductor body and at least a part of the electrode layers, the memory film including a charge storage portion; and
a first semiconductor layer of the first conductivity type provided in the second portion, a concentration of a first conductivity type carrier of the first semiconductor layer being higher than a concentration of the first conductivity type carrier of the third portion,
the second portion including a channel of a selection transistor,
the third portion including a channel of a memory cell.

2. The semiconductor device according to claim 1, wherein a concentration of the first conductivity type carrier of the first portion is lower than the concentration of the first conductivity type carrier of the first semiconductor layer.

3. The semiconductor device according to claim 1, further comprising a second semiconductor layer of a second conductivity type provided in the first portion.

4. The semiconductor device according to claim 1, further comprising an insulating layer provided on the first portion.

5. The semiconductor device according to claim 4, further comprising a core layer provided on the third portion, wherein
the core layer is insulative, and
the core layer has a different composition than the insulating layer.

6. The semiconductor device according to claim 4, further comprising a second semiconductor layer of a second conductivity type provided in the first portion, wherein
a P-N junction between the first semiconductor layer and the second semiconductor layer in the semiconductor body is adjacent to the insulating layer.

7. The semiconductor device according to claim 1, wherein
the concentration of the first conductivity type carrier of the third portion is 1×10¹⁷ cm⁻³ or less, and
the concentration of the first conductivity type carrier of the first semiconductor layer is not less than 1×10¹⁸ cm⁻³ and not more than 5×10¹⁹ cm⁻³.

8. The semiconductor device according to claim 1, wherein a thickness of the second portion is thinner than a thickness of the third portion in a direction perpendicular to the stacking direction.

9. The semiconductor device according to claim 1, wherein a thickness of the second portion is thinner than a thickness of the first portion and a thickness of the third portion in a direction perpendicular to the stacking direction.

10. The semiconductor device according to claim 9, wherein a thickness of the first portion is substantially equal to a thickness of the third portion in the direction perpendicular to the stacking direction.

11. A semiconductor device, comprising:
a stacked body including a plurality of electrode layers stacked with an insulator interposed;
a semiconductor body of a first conductivity type extending through the stacked body in a stacking direction of the stacked body, the semiconductor body including, along the stacking direction of the stacked body, a first portion, a second portion, and a third portion, the second portion being provided between the first portion and the third portion, a thickness of the second portion being thinner than a thickness of the first portion and a thickness of the third portion in a direction perpendicular to the stacking direction; and
a memory film provided between the semiconductor body and at least a part of the electrode layers, the memory film including a charge storage portion,
the second portion including a channel of a selection transistor,
the third portion including a channel of a memory cell.

12. The semiconductor device according to claim 11, further comprising a semiconductor layer of a second conductivity type provided in the first portion.

13. The semiconductor device according to claim 11, further comprising an insulating layer provided on the first portion.

14. The semiconductor device according to claim 13, further comprising a core layer provided on the third portion, wherein
the core layer is insulative, and
the core layer has a different composition than the insulating layer.

15. The semiconductor device according to claim 13, further comprising a first semiconductor layer of the first conductivity type provided in the second portion and a second semiconductor layer of a second conductivity type provided in the first portion, wherein
a P-N junction between the first semiconductor layer and the second semiconductor layer in the semiconductor body is adjacent to the insulating layer.

16. The semiconductor device according to claim 11, wherein a thickness of the first portion is substantially equal to a thickness of the third portion in the direction perpendicular to the stacking direction.

17. A method for manufacturing a semiconductor device, comprising:
forming a stacked body, the stacked body including a first layer and a second layer multiply stacked alternately, the second layer being of a material different from a material of the first layer;
making a hole in the stacked body;
forming a memory film in the hole;
forming a semiconductor body of a first conductivity type on the memory film;
forming a core layer on the semiconductor body, the core layer being insulative;
exposing a first portion of the semiconductor body in the hole by causing the core layer to recede;
forming an insulating layer on the first portion, the insulating layer having a different composition than the core layer; and
exposing a second portion of the semiconductor body in the hole by causing the core layer to recede.

18. The method for manufacturing the semiconductor device according to claim 17, further comprising forming a semiconductor layer of the first conductivity type in the second portion by introducing a first conductivity type carrier into the semiconductor body after the exposing of the second portion.

19. The method for manufacturing the semiconductor device according to claim 17, further comprising reducing a thickness of the second portion in a direction perpendicular to a stacking direction of the stacked body by etching the semiconductor body after the exposing of the second portion.

20. The method for manufacturing the semiconductor device according to claim 17, wherein a receded amount of the core layer is set to form the second portion to include a region used to form a channel of a selection transistor.
